(19) United States
(12) Patent Application Publication
(10) Pub. No.: US 2023/0371252 A1
(43) Pub. Date: Nov. 16, 2023

(54) MEMORY DEVICE, CIRCUIT STRUCTURE AND PRODUCTION METHOD THEREOF

(71) Applicant: MACRONIX International Co., Ltd., Hsinchu (TW)

(72) Inventors: Kuan-Yuan Shen, Hsinchu County (TW); Teng-Hao Yeh, Hsinchu County (TW); Chia-Jung Chiu, Hsinchu County (TW)

(73) Assignee: MACRONIX International Co., Ltd., Hsinchu (TW)

(21) Appl. No.: 17/742,159

(22) Filed: May 11, 2022

(51) Int. Cl. H01L 27/11526; H01L 23/522; H01L 23/528; H01L 27/11551; H01L 27/11573; H01L 27/11578

(52) U.S. Cl. CPC H01L 27/11526; H01L 23/5226; H01L 23/5283; H01L 27/11551; H01L 27/11573; H01L 27/11578

(57) ABSTRACT

A three-dimension memory device, a memory circuit and a production method are provided. The three-dimension memory circuit includes a peripheral circuit, a metal layer, a buffer layer, a poly silicon layer, and a via array. The peripheral circuit is disposed on a substrate. The metal layer covers on the peripheral circuit and is electrically coupled to the peripheral circuit. The buffer layer is disposed on the metal layer. The poly silicon layer receives a reference ground voltage and is disposed on the buffer layer. The via array is disposed in the buffer layer and is used to electrically connect the metal layer and the poly silicon layer.

### BACKGROUND

### Technical Field

The disclosure relates to a memory device, a circuit structure and a production method thereof, and more particularly, to the memory device, the circuit structure and the production method which effectively generates a discharge path of an accumulated charge and a production method thereof.

### Description of Related Art

In the manufacturing technology of the three-dimensional memory device, it is a common means to use high-density plasma to perform an etching process. The application of such high-density plasma often results in the accumulation of excessively high-energy charges in the memory device, resulting in the risk of arcing effect. Therefore, in the production process, how to improve a discharge path of accumulated charges to reduce the risk of arcing effect is an important issue for those skilled in the art.

### SUMMARY

The disclosure provides a memory device, a circuit structure and a production method thereof. The circuit structure provides a discharge path, so as to perform a discharge operation of an accumulated charge in a production process.

A circuit structure in the disclosure includes a peripheral circuit, a metal layer, a buffer layer, a poly silicon layer, and a via array. The peripheral circuit is disposed on a substrate. The metal layer covers on the peripheral circuit, and is electrically coupled to the peripheral circuit. The buffer layer is disposed on the metal layer. The poly silicon layer receives a reference ground voltage, and is formed on the buffer layer. The via array is disposed in the buffer layer, and is used to electrically connect the metal layer and the poly silicon layer. At least one first discharge path is disposed between the poly silicon layer and the substrate through the via array, the metal layer, and the peripheral circuit.

The memory device in the disclosure includes a substrate, multiple driving circuits, multiple via arrays, multiple poly silicon layers, and a peripheral poly silicon layer. The driving circuits are formed on the substrate. The driving circuits respectively correspond to multiple memory blocks. The poly silicon layers are electrically coupled to the driving circuits respectively through the via arrays and a metal layer. The peripheral poly silicon layer is formed on peripheries of the poly silicon layers, and the peripheral poly silicon layer and the poly silicon layers receive a reference ground voltage.

A production method of the circuit structure of the disclosure includes the following steps. A peripheral circuit is formed on a substrate. A metal layer is formed to cover on the peripheral circuit, and the metal layer is electrically coupled to the peripheral circuit. A buffer layer is formed to cover on the metal layer. A poly silicon layer is formed to cover the buffer layer, so that the poly silicon layer receives a reference ground voltage. A via array is formed in the buffer layer, so that the via array is electrically connected to the metal layer and the poly silicon layer. At least one first discharge path is formed between the poly silicon layer and the substrate through the via array, the metal layer, and the peripheral circuit.

Based on the above, in the circuit structure in the disclosure, by disposing the via array in the buffer layer, the poly silicon layer may be electrically coupled to the peripheral circuit through the via array, thereby generating at least one discharge path between the poly silicon layer and the substrate. In this way, the accumulated charge generated on the poly silicon layer due to the process operation may be discharged through the above discharge path, which effectively reduces the possibility of damage to the circuit structure due to the accumulated charge.

### BRIEF DESCRIPTION OF THE DRAWINGS

FIG. 1 is a schematic cross-sectional view illustrating a cross structure of a circuit structure according to an embodiment of the disclosure.

FIG. 2 is a schematic view illustrating a discharge operation of an accumulated charge in another embodiment in a production process of the circuit structure according to the embodiment of the disclosure.

FIG. 3 is a schematic cross-sectional view illustrating a cross structure of a circuit structure according to another embodiment of the disclosure.

FIG. 4 is a schematic three-dimensional view illustrating a structure of a memory device according to an embodiment of the disclosure.

FIG. 5 is a top view illustrating the memory device of FIG. 4 according to the embodiment of the disclosure.

FIG. 6 is a schematic view illustrating an equivalent circuit of a memory device according to an embodiment of the disclosure.

FIG. 7 is a schematic three-dimensional view illustrating an architecture of a memory device according to an embodiment of the disclosure.

FIG. 8A is a schematic view illustrating a memory block of a memory device according to an embodiment of the disclosure.

FIG. 8B is a schematic view illustrating a dimensional relationship between the memory block and a wafer.

FIGS. 9A to 9G are schematic views illustrating a production process of a t circuit structure according to an embodiment of the disclosure.

### DETAILED DESCRIPTION OF DISCLOSED EMBODIMENTS

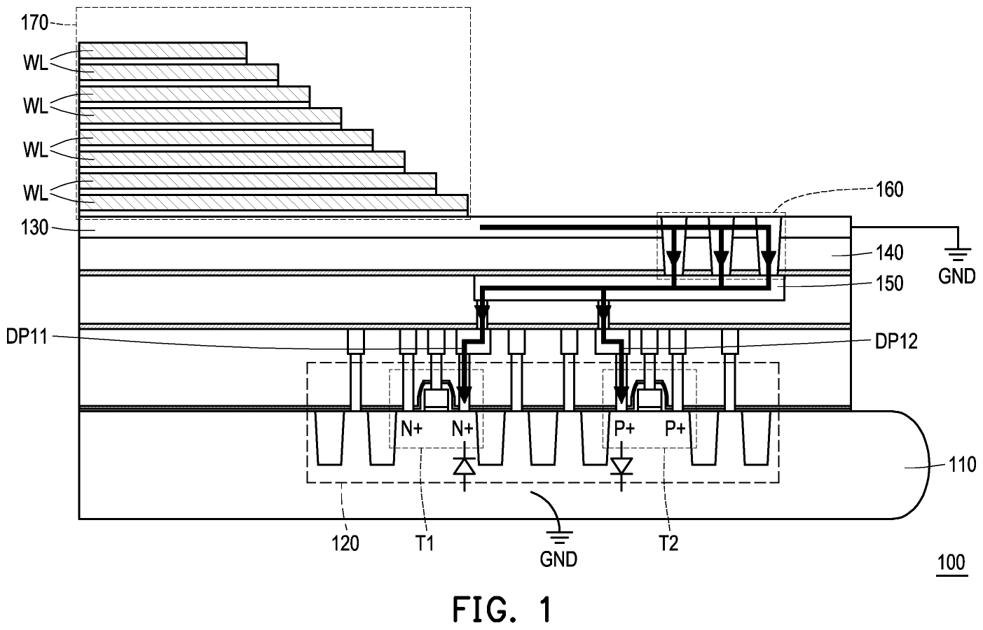

Referring to FIG. 1, FIG. 1 is a schematic cross-sectional view illustrating a structure of a circuit structure according to an embodiment of the disclosure. A circuit structure 100 includes a substrate 110, a peripheral circuit 120, a poly silicon layer 130, a buffer layer 140, a metal layer 150, a via array 160, and a word line structure 170 formed by multiple word lines WL. The peripheral circuit 120 is disposed in the substrate 110. In this embodiment, the peripheral circuit 120 includes transistors T1 and T2. The transistor T1 may be an N-type transistor, and has a source and a drain formed by an N-type heavily doped region (N+). The transistor T2 may be a P-type transistor, and has a source and a drain formed by a P-type heavily doped region (P+).

The metal layer 150 covers on the peripheral circuit 120, and may be electrically coupled to one of the heavily doped regions of the transistors T1 and T2 through multiple contact windows. The buffer layer 140 covers on the metal layer 150, and the poly silicon layer 130 covers on the buffer layer 140. The via array 160 is disposed in the buffer layer 140, and is used to electrically couple the poly silicon layer 130 and the metal layer 150. In this way, a discharge path DP11 may be formed between the poly silicon layer 130 and the substrate 110 through the via array 160, the metal layer 150, and the heavily doped region N+ of the transistor T1 in the peripheral circuit 120. Another discharge path DP12 may be formed between the poly silicon layer 130 and the substrate 110 through the via array 160, the metal layer 150, and the heavily doped region P+ of the transistor T2 in the peripheral circuit 120.

It is worth mentioning that in this embodiment, the poly silicon layer 130 receives a reference ground voltage GND. In addition, the substrate 110 may also receive the reference ground voltage GND.

In this embodiment, in a production process of the circuit structure 100, when plasma is applied to the poly silicon layer 130 to generate an accumulated charge on the poly silicon layer 130, the accumulated charge on the poly silicon layer 130 may be discharged through the discharge paths DP11 And DP12. When a voltage on the poly silicon layer 130 is negative (e.g., not greater than 0.7 volts), the accumulated charge may be discharged through the discharge path DP11. When the voltage on the poly silicon layer 130 is positive (e.g., greater than 0.7 volts), the accumulated charge may be discharged through the discharge path DP12.

It is worth mentioning that in other embodiments of the disclosure, the peripheral circuit 120 may only have the transistor T1. The heavily doped region N+ of the transistor T1 may also provide a discharge operation of a bipolar charge. When the voltage on the poly silicon layer 130 is negative (e.g., less than 0.7 volts), the accumulated charge may be discharged through the discharge path DP11. When the voltage on the poly silicon layer 130 is positive and greater than a junction breakdown voltage between the heavily doped region N+ of the transistor T1 and the substrate 110, the accumulated charge may also be discharged through the discharge path DP11.

Incidentally, the word lines WL on the word line structure 170 are disposed in a stepped manner, and are disposed on the poly silicon layer 130.

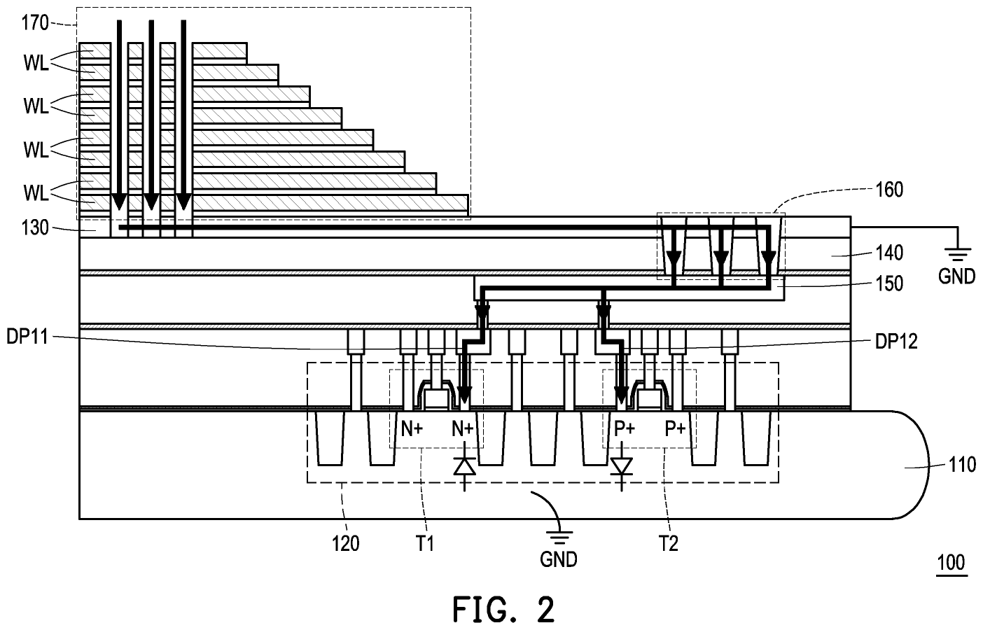

Hereinafter, referring to FIG. 2 together, FIG. 2 is a schematic view illustrating a discharge operation of an accumulated charge in another embodiment in a production process of the circuit structure according to the embodiment of the disclosure. The circuit structure 100 of FIG. 1 is also described. When an etching process is performed for the word lines WL on the circuit structure 100, an etching operation is performed by applying the plasma to an upper surface of the word line structure 170, and the word line structure 170 is formed with multiple grooves that may expose the buffer layer 140. Under the etching operation, the charge accumulated in the poly silicon layer 130 may also be discharged through the discharge paths DP11 and DP12, which may ensure that the circuit structure 100 is not damaged by the accumulated charge in the production process.

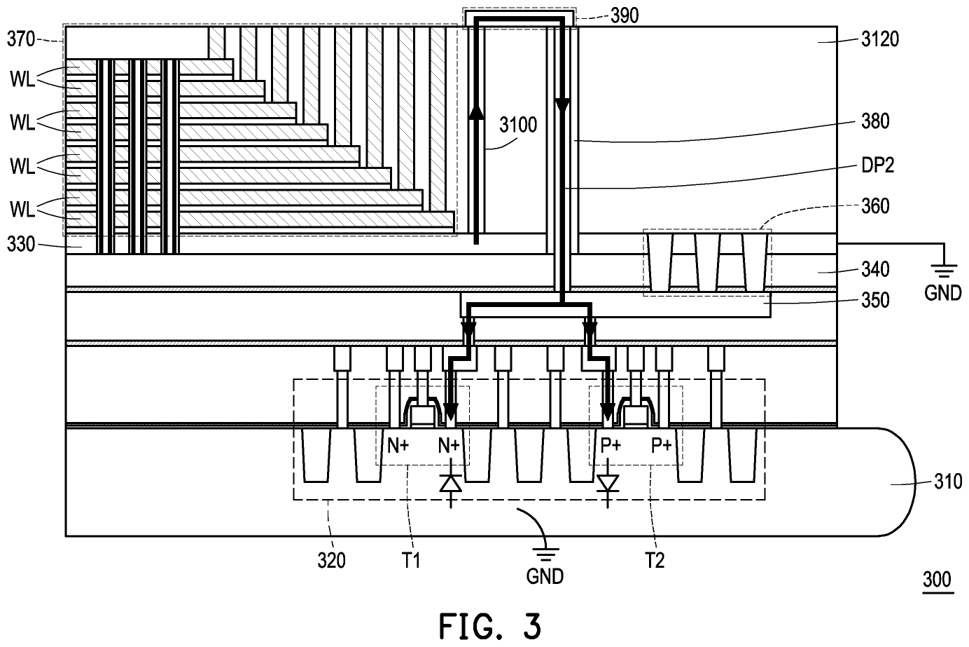

Hereinafter, referring to FIG. 3, FIG. 3 is a schematic cross-sectional view illustrating a structure of a circuit structure according to another embodiment of the disclosure. A circuit structure 300 includes a substrate 310, a peripheral circuit 320, a poly silicon layer 330, a buffer layer 340, a metal layer 350, a via array 360, a word line structure 370 formed by the word lines, a transmission array through via 380, a conductive line structure 390, and a contact window 3100.

The peripheral circuit 320 is formed in substrate 310. In this embodiment, the peripheral circuit 320 includes the transistors T1 and T2. The transistor T1 may be the N-type transistor, and has the source and the drain formed by the N-type heavily doped region (N+). The transistor T2 may be the P-type transistor, and has the source and the drain formed by the P-type heavily doped region (P+). The metal layer 350 covers on the peripheral circuit 320, and may be electrically coupled to one of the heavily doped regions of the transistors T1 and T2 through the contact windows. The buffer layer 340 covers on the metal layer 350, and the poly silicon layer 330 covers on the buffer layer 340. The via array 360 is formed in the buffer layer 340, and is used to electrically couple the poly silicon layer 330 and the metal layer 350. In this way, a discharge path may be formed between the poly silicon layer 330 and the substrate 310 through the via array 360, the metal layer 350, and the heavily doped region N+ of the transistor T1 in the peripheral circuit 320. Another discharge path may be formed between the poly silicon layer 330 and the substrate 310 through the via array 360, the metal layer 350, and the heavily doped region P+ of the transistor T2 in the peripheral circuit 320.

It is worth mentioning that in this embodiment, the circuit structure 300 further includes the transmission array through via 380. The transmission array through via 380 is formed in an insulating layer 3120. The transmission array through via 380 penetrates through the poly silicon layer 330 and the buffer layer 340, and is electrically connected to the metal layer 350. In addition, the conductive line structure 390 is formed above the insulating layer 3120. One end of the conductive line structure 390 is electrically coupled to the metal layer 350, and the other end of the conductive line structure 390 is electrically coupled to the poly silicon layer 330 through the contact window 3100.

In this way, in this embodiment, another discharge path DP2 may be formed between the poly silicon layer 330 and the substrate 310 through the conductive line structure 390, the transmission array through via 380, the metal layer 350, and the peripheral circuit 320. The discharge path DP2 may be applied to a normal operation of the circuit structure 300 to provide the discharge path of the poly silicon layer 330.

In this embodiment, the transmission array through via 380, the conductive line structure 390, and the contact window 3100 may be completed through a back-end process.

It may be seen from the above description that in an architecture of the circuit structure 300 in the embodiment of the disclosure, the discharge paths may be formed, and the accumulated charge on the poly silicon layer 330 may be effectively discharged to maintain the normal operation of the circuit structure 300.

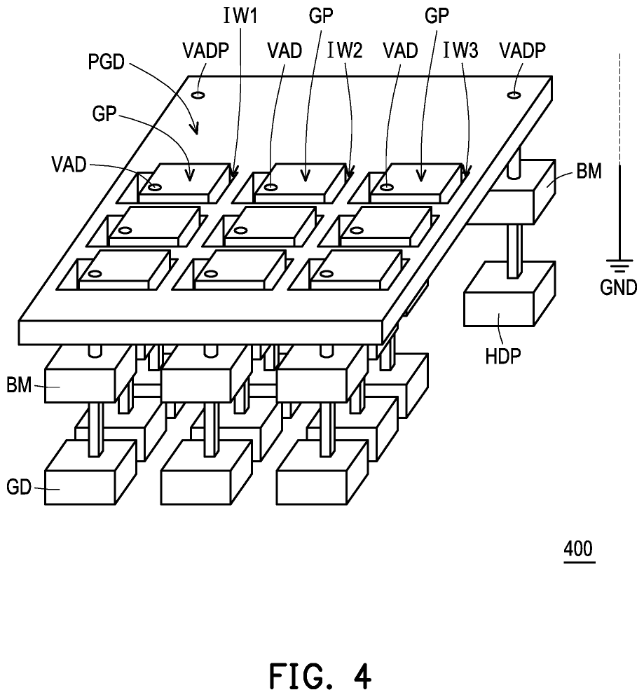

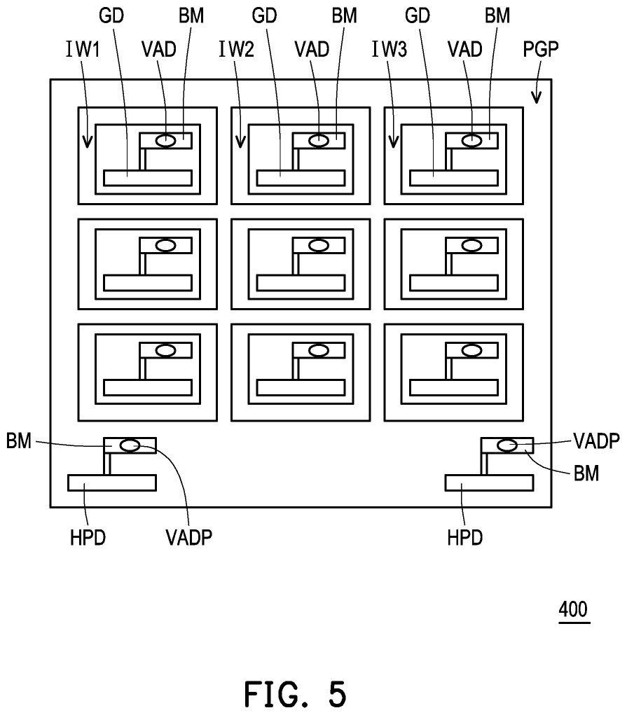

Hereinafter, referring to FIGS. 4 and 5, FIG. 4 is a schematic three-dimensional view illustrating a structure of a memory device according to an embodiment of the disclosure, and FIG. 5 is a top view illustrating the memory device of FIG. 4 according to the embodiment of the disclosure. A memory device 400 may be a three-dimensional memory device, includes a substrate (not shown), multiple driving circuits GD, multiple via arrays VAD, multiple poly silicon layers GP, and a peripheral poly silicon layer PGP. The driving circuits GD may be disposed in the substrate in the form of an array. The poly silicon layers GP respectively correspond to the driving circuits GD for arrangement. The via arrays VAD are respectively formed on the poly silicon layers GP. The driving circuits GD are electrically coupled to the poly silicon layers GP through multiple metal layers BM and the via arrays VAD, respectively.

In this embodiment, the poly silicon layers GP may respectively correspond to multiple memory blocks. At least one discharge path may be formed between the poly silicon layer GP and the substrate through the corresponding via array VAD, the corresponding metal layer BM, and the corresponding driving circuit GD as a peripheral circuit. A formation method of the discharge path in this embodiment is the same as that of the discharge paths DP11 and DP12 in the embodiment of FIG. 1. Therefore, the same details will not be repeated in the following.

The via array VAD may be formed at a corner of the poly silicon layer GP.

Incidentally, each of the metal layers BM and each of the corresponding driving circuits GD may be electrically coupled to each other through the contact window.

The poly silicon layer GP may receive the reference ground voltage GND.

On the other hand, the peripheral poly silicon layer PGP is formed on a periphery of the poly silicon layer GP. Multiple separation windows IW1 to IW3 (which is three in this embodiment) may be formed in the peripheral poly silicon layer PGP, and the one or more poly silicon layers GP may be disposed in each of the separation windows IW1 to IW3. The memory device 400 shown in this embodiment may be a NOR flash memory device or an AND flash memory device.

A peripheral via array VADP may be formed at a corner of the peripheral poly silicon layer PGP. Each of the peripheral via arrays VADP may be electrically coupled to the metal layer BM, and coupled to a heavily doped region HDP in the substrate through the contact window. The heavily doped region HDP may be a part of a driving circuit disposed in the substrate.

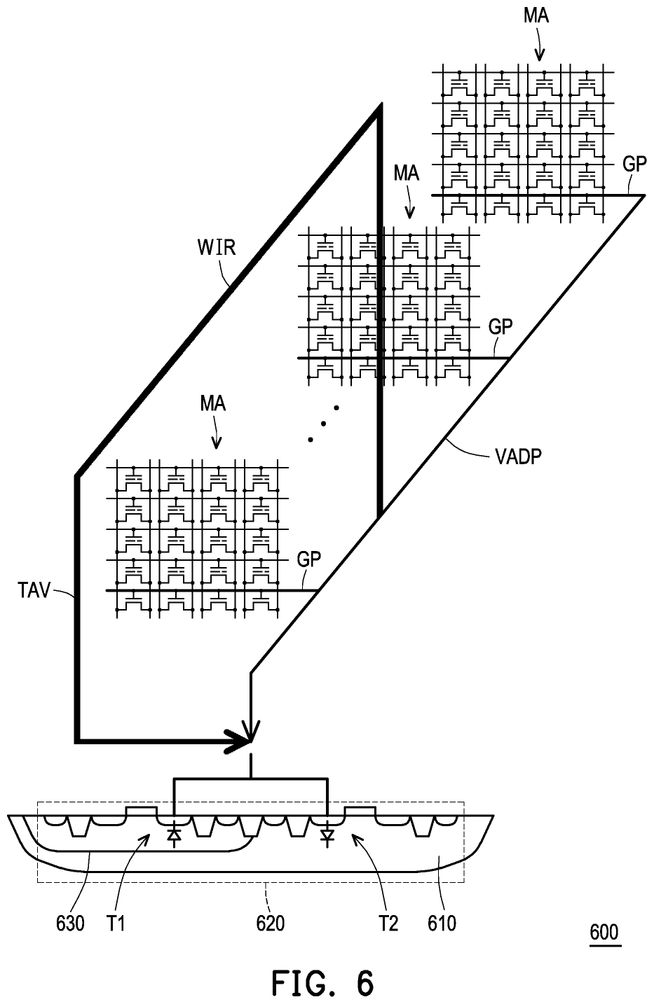

Referring to FIG. 6, FIG. 6 is a schematic view illustrating an equivalent circuit of a memory device according to an embodiment of the disclosure. A memory device 600 includes multiple memory cell arrays MA and a peripheral circuit 620. The poly silicon layers GP to which the memory cell arrays MA are coupled may be electrically coupled to the peripheral circuit 620 serving as a driving circuit through the corresponding via arrays, respectively. A discharge path is formed by the poly silicon layer GP to which the memory cell array MA is coupled and a coupling path VADP of the peripheral circuit 620. In addition, the memory device 600 further includes a transmission array through via TAV and a conductive line structure WIR. One end of the conductive line structure WIR is electrically coupled to the poly silicon layer GP through a contact window, and the other end of the conductive line structure WIR is coupled to the transmission array through via TAV. The transmission array through via TAV is electrically coupled to the peripheral circuit 620. In this way, the contact window, the conductive line structure WIR, and the transmission array through via TAV may form another discharge path between a substrate of the peripheral circuit 620 and the poly silicon layer GP.

The peripheral circuit 620 includes transistors T1 and T2. The transistor T2 is formed in a well 610. The transistor T1 may be formed in a well 630. In this embodiment, the well 630 may be formed on the well 610. Besides, the transistors T1 and T2 may have different conductive types. For example, the transistor T2 may be P-type transistor, and the transistor T1 may be N-type transistor. Correspondingly, the wells 610 and 630 may have different conductive types. For example, the well 610 may be N-type well, and the well 630 may be P-type well. On the other and, in this embodiment, the well 610 may receive a voltage with positive polarity, and the well 630 may receive a voltage with negative polarity.

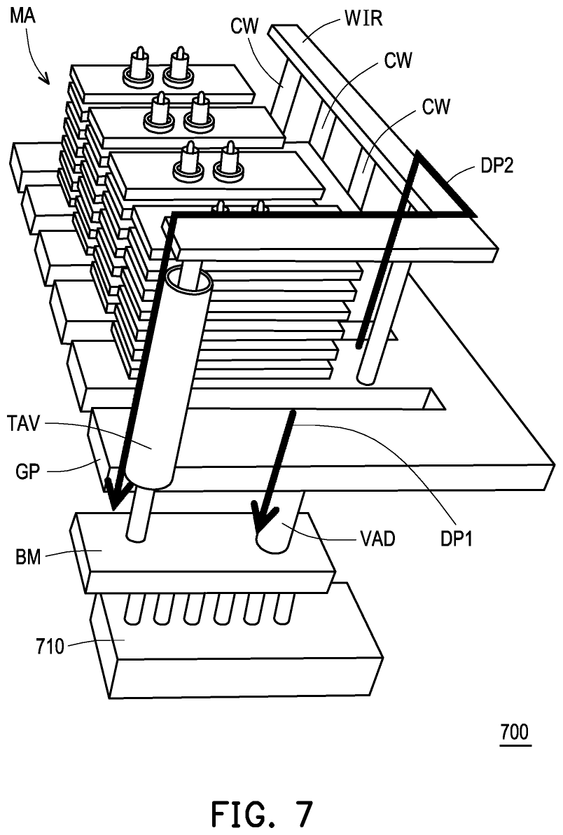

Referring to FIG. 7, FIG. 7 is a schematic three-dimensional view illustrating an architecture of a memory device according to an embodiment of the disclosure. A memory device 700 includes the memory cell arrays MA. The memory cell array MA is coupled to the poly silicon layer GP, and the poly silicon layer GP receives the reference ground voltage. In this embodiment, the poly silicon layer GP is electrically coupled to the metal layer BM through the via array VAD. The metal layer BM is electrically coupled to a peripheral circuit 710 through the contact window. The via array VAD and the metal layer BM provide a first discharge path DP1 between the poly silicon layer GP and a substrate of the peripheral circuit 710. In addition, the memory device 700 further includes the contact windows CW, the conductive line structure WIR, and the transmission array through via TAV. The contact windows CW, the conductive line structure WIR, and the transmission array through via TAV are electrically coupled between the poly silicon layer GP and the peripheral circuit 710 in sequence and provide a second discharge path DP2.

The memory device 700 of this embodiment provides the double discharge paths, which may effectively discharge the accumulated charge on the poly silicon layer GP, and may effectively ensure the safety of the memory device 700.

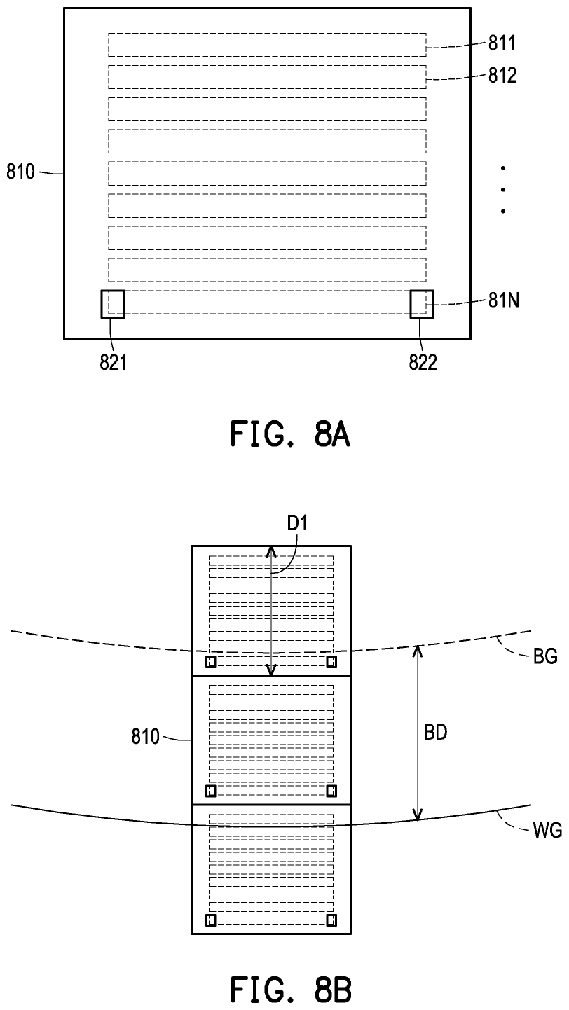

Hereinafter, referring to FIGS. 8A and 8B, FIG. 8A is a schematic view illustrating a memory block of a memory device according to an embodiment of the disclosure, and FIG. 8B is a schematic view illustrating a dimensional relationship between the memory block and a wafer. In FIG. 8A, a memory block 810 of the memory device according to the embodiment of the disclosure may include multiple memory cell arrays 811 to 81N. Peripheral circuits (e.g., word line driving circuits) 821 and 822 in the memory block 810 may be disposed on opposite corners of the same side in the memory block 810, which may improve the efficiency of charge discharge.

In FIG. 8B, in order to ensure that a discharge path in the memory block 810 is not cut off, a length D1 of the memory block 810 is less than a bevel distance BD between a bevel boundary BG and a wafer boundary WG of the wafer.

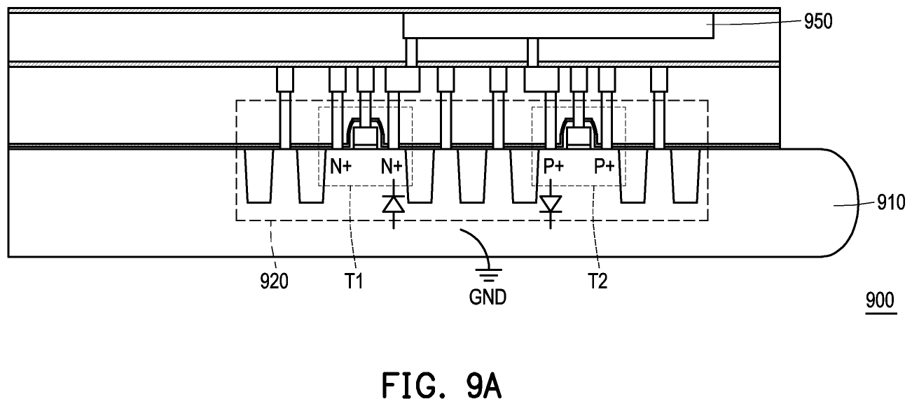

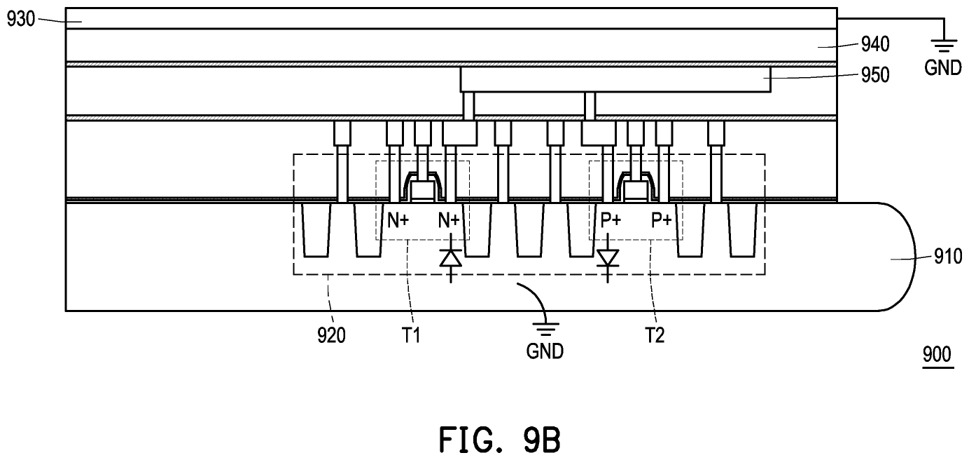

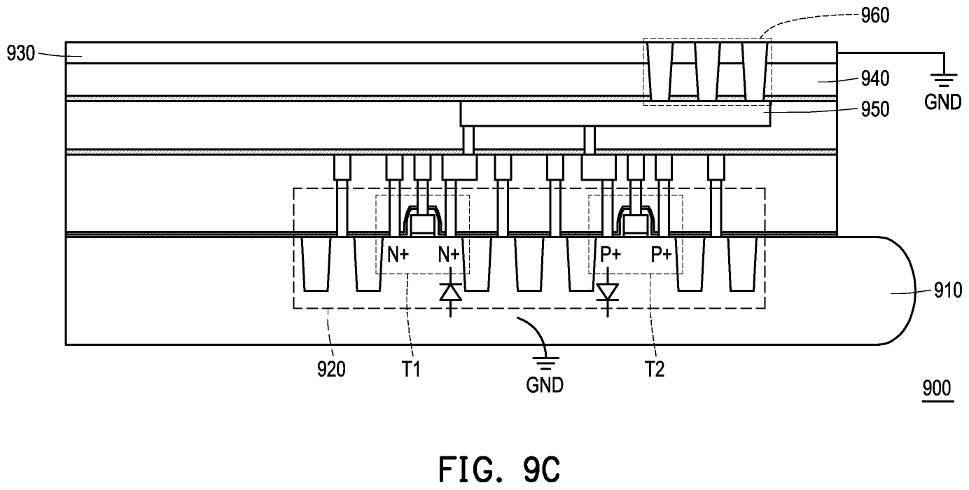

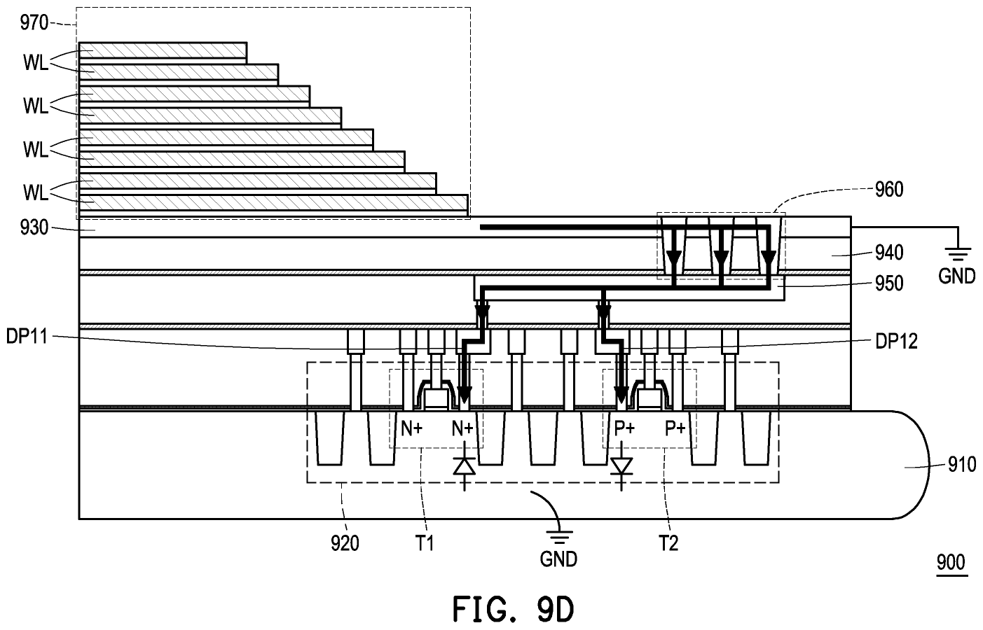

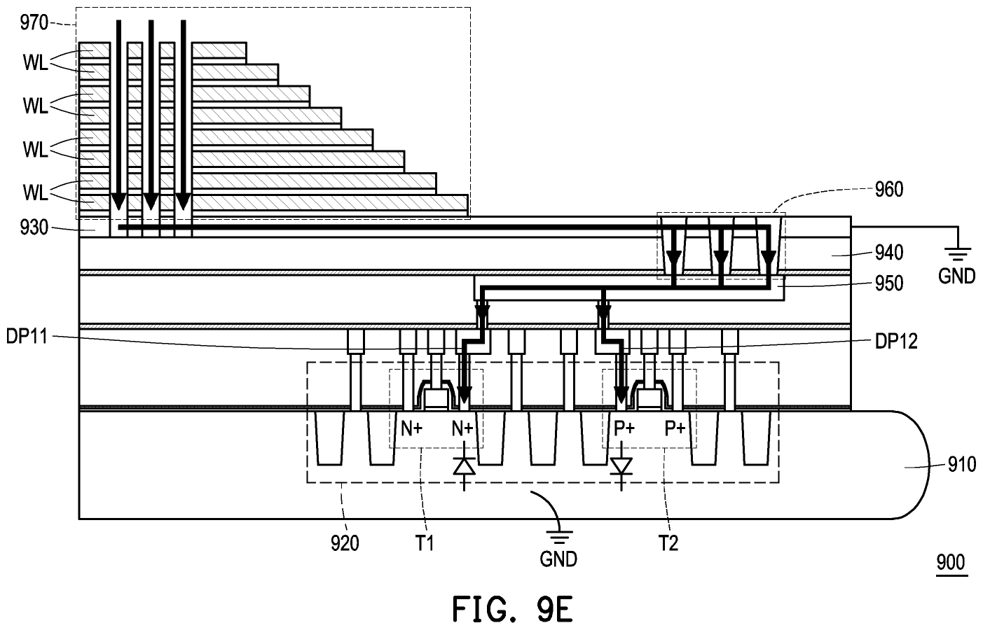

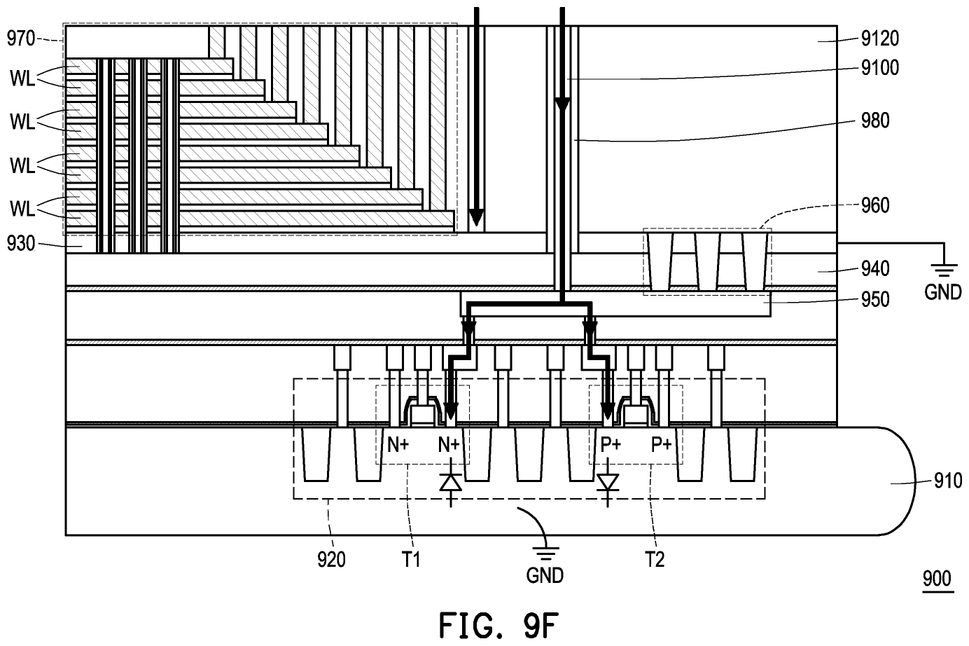

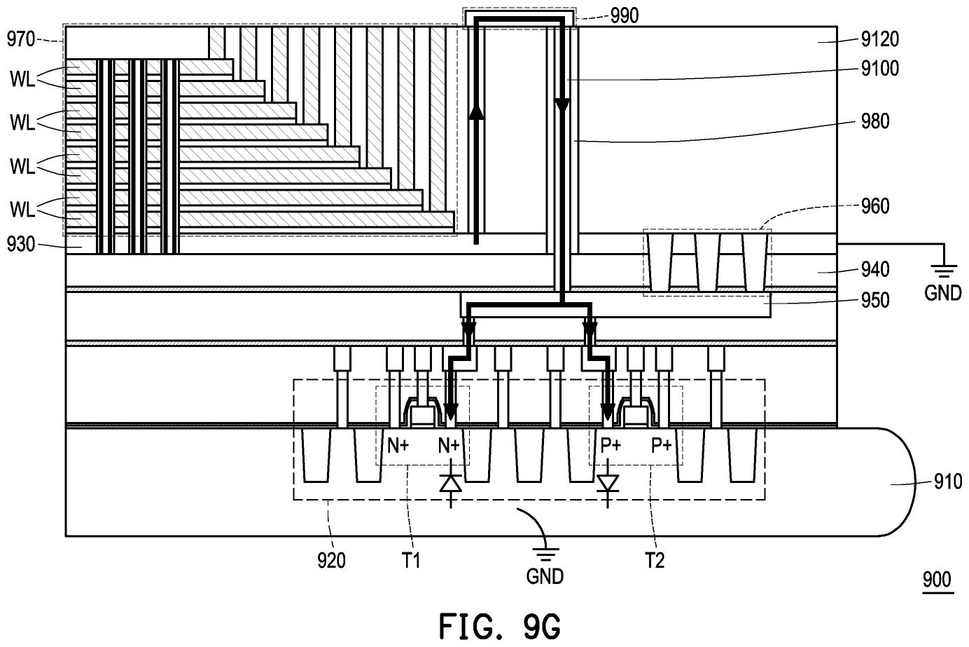

Referring to FIGS. 9A to 9G, FIGS. 9A to 9G are schematic views illustrating a production process of a circuit structure according to an embodiment of the disclosure. In FIG. 9A, a circuit structure 900 includes a substrate 910, a peripheral circuit 920, and a metal layer 950. The peripheral circuit 920 is formed in substrate 910. The metal layer 950 is formed on the peripheral circuit 920, and is electrically coupled to the peripheral circuit 920 through the contact windows. Next, in FIG. 9B, a buffer layer 940 is formed on the metal layer 950 and covers the metal layer 950. A poly silicon layer 930 is formed on the buffer layer 940 and covers the buffer layer 940.

In FIG. 9C, a via array 960 is formed in the buffer layer 940. The via array 960 is used to electrically couple the poly silicon layer 930 and the metal layer 950. Through the via array 960, between the poly silicon layer 930 and the substrate 910, there may be a discharge path formed by the via array 960, the metal layer 950, and the peripheral circuit 920.

In FIG. 9D, a word line structure 970 formed by the word lines may be formed on the poly silicon layer 930. The word line structure 970 may have a stepped shape. In FIG. 9E, the plasma is applied to an upper surface of the word line structure 970 to perform the etching operation. By the etching operation, the buffer layer 940 in part of the word line structure 970 may be exposed. In addition, the discharge path formed by the via array 960, the metal layer 950, and the peripheral circuit 920 may continuously perform the discharge operation on an accumulation circuit generated by the plasma.

In FIG. 9F, an insulating layer 9120 may be formed on the poly silicon layer 930, and the insulating layer 9120 may cover the poly silicon layer 930 and the word line structure 970. In addition, a transmission array through via 980 and a contact window 9100 may be formed in the insulating layer 9120. The transmission array through via 980 may penetrate through the poly silicon layer 930 and the buffer layer 940, and be electrically coupled to the metal layer 950. The contact window 9100 is electrically coupled to the poly silicon layer 930. In FIG. 9G, a conductive line structure 990 is formed in the insulating layer 9120, and the conductive line structure 990 is electrically coupled between the contact window 9100 and the transmission array through via 980. In this way, the contact window 9100, the conductive line structure 990, the transmission array through via 980, and the metal layer 950 may form another discharge path between the poly silicon layer 930 and the peripheral circuit 920.

Based on the above, in the circuit structure of the disclosure, by forming the via array, the poly silicon layer receiving the reference ground voltage may be electrically coupled to the peripheral circuit through the via array, and coupled to the substrate through the heavily doped region in the peripheral circuit. In this way, the discharge path may be formed between the poly silicon layer and the substrate, and the discharge operation may be performed for the accumulated charge on the poly silicon layer. In the production process, the circuit structure may be effectively protected from being damaged by the accumulated charge generated by the plasma.

What is claimed is:

1. A circuit structure comprising:
a peripheral circuit disposed on a substrate;
a metal layer covering on the peripheral circuit and electrically coupled to the peripheral circuit;
a buffer layer disposed on the metal layer;
a poly silicon layer receiving a reference ground voltage and disposed on the buffer layer; and
a via array formed in the buffer layer and used to electrically connecting the metal layer and the poly silicon layer.

2. The circuit structure according to claim 1, wherein the peripheral circuit is a driving circuit, the driving circuit comprises at least one transistor, and the via array is electrically coupled to at least one heavily doped region of the at least one transistor.

3. The circuit structure according to claim 1, wherein at least one first discharge path is formed between the poly silicon layer and the substrate through the via array, the metal layer, and the peripheral circuit.

4. The circuit structure according to claim 1, further comprising:
a transmission array through via formed in an insulating layer and electrically connected to the metal layer; and
a conductive line structure formed on the insulating layer, electrically coupled to the transmission array through via, and electrically coupled to the poly silicon layer through a contact window,
wherein the insulating layer covers on the poly silicon layer, and at least one second discharge path is formed between the poly silicon layer and the substrate through the conductive line structure, the transmission array through via, the metal layer, and the peripheral circuit.

5. The circuit structure according to claim 1, wherein the peripheral circuit comprises:
a first transistor, disposed in a first well, wherein the first well receives a first voltage;
a second transistor, disposed in a second well, wherein the second well receives a second voltage,
wherein conductive types of the first transistor and the second transistor are different, conductive types of the first well and the second well are different and voltage polarity of the first voltage and the second voltage are different.

6. The circuit structure according to claim 4, further comprising:
a plurality of word lines formed on the poly silicon layer in a stacked manner.

7. A memory device, comprising:
a substrate;
a plurality of driving circuits formed on the substrate, wherein the driving circuits respectively correspond to a plurality of memory blocks;
a plurality of via arrays;
a plurality of poly silicon layers electrically coupled to the driving circuits respectively through the via arrays and a plurality of metal layers; and
a peripheral poly silicon layer formed on peripheries of the poly silicon layers, wherein the peripheral poly silicon layer and the poly silicon layers receive a reference ground voltage.

8. The memory device according to claim 7, further comprising:
a plurality of peripheral via arrays used to couple the peripheral poly silicon layer to a plurality of peripheral metal layers; and
a plurality of heavily doped regions respectively coupled to the peripheral metal layers.

9. The memory device according to claim 8, wherein the peripheral via arrays are respectively disposed at a plurality of corners of the peripheral poly silicon layer.

10. The memory device according to claim 7, wherein the via arrays are respectively disposed at corners of the poly silicon layers.

11. The memory device according to claim 7, wherein the peripheral poly silicon layer forms a plurality of separation windows, and each of the separation windows is used to accommodate at least one memory block.

12. The memory device according to claim 11, wherein a length of the at least one memory block is less than a bevel distance between a bevel boundary and a wafer boundary of a wafer.

13. A production method of a circuit structure, comprising:
forming a peripheral circuit on a substrate;
forming a metal layer to cover on the peripheral circuit, and electrically coupling the metal layer to the peripheral circuit;
forming a buffer layer to cover on the metal layer;
forming a poly silicon layer to cover the buffer layer, so that the poly silicon layer receives a reference ground voltage;
forming a via array in the buffer layer, so that the via array is electrically connected to the metal layer and the poly silicon layer; and
forming at least one first discharge path between the poly silicon layer and the substrate through the via array, the metal layer, and the peripheral circuit.

14. The production method of the circuit structure according to claim 13, further comprising:
electrically coupling the via array to at least one heavily doped region of at least one transistor in the peripheral circuit.

15. The production method of the circuit structure according to claim 13, further comprising:
providing the at least one first discharge path to discharge an accumulated charge on the poly silicon layer when plasma is to be applied to the poly silicon layer.

16. The production method of the circuit structure according to claim 13, further comprising:
forming a transmission array through via in an insulating layer, so that the transmission array through via is electrically connected to the metal layer, wherein the insulating layer covers on the poly silicon layer;
forming a conductive line structure on the insulating layer, so that the conductive line structure is electrically coupled to the transmission array through via;
electrically coupled the conductive line structure to the poly silicon layer through a contact window; and
forming at least one second discharge path between the poly silicon layer and the substrate through the conductive line structure, the transmission array through via, the metal layer, and the peripheral circuit.

17. The production method of the circuit structure according to claim 16, further comprising:
forming a plurality of word lines on the poly silicon layer in a stacked manner; and
providing the at least one first discharge path and the at least one second discharge path to discharge an accumulated charge on the poly silicon layer when plasma is applied to the word lines to perform an etching operation.

18. The production method of the circuit structure according to claim 13, wherein the via array is formed at a corner of the poly silicon layer.

19. The production method of the circuit structure according to claim 13, wherein the poly silicon layer corresponds to a memory block, and a length of the memory block is less than a bevel distance between a bevel boundary and a wafer boundary of a wafer.

20. The production method of the circuit structure according to claim 13, further comprising:
forming a peripheral poly silicon layer on a periphery of the poly silicon layer, so that the peripheral poly silicon layer receives the reference ground voltage; and
forming a plurality of peripheral via arrays, so that the peripheral poly silicon layer is coupled to a plurality of heavily doped regions through a plurality of peripheral metal layers.
